(19) United States
(12) Patent Application Publication
(10) Pub. No.: US 2021/0042111 A1
(43) Pub. Date: Feb. 11, 2021

(54) EFFICIENT ENCODING OF HIGH FANOUT COMMUNICATIONS

(71) Applicant: Microsoft Technology Licensing, LLC, Redmond, WA (US)

(72) Inventors: Brandon Zachary FRY, Woodinville, WA (US); David Tennyson HARPER, III, Seattle, WA (US); Gagan GUPTA, Bellevue, WA (US); Douglas Christopher BURGER, Bellevue, WA (US)

(21) Appl. No.: 16/532,535

(22) Filed: Aug. 6, 2019

(51) Int. Cl. G06F 9/22; G06F 9/30; G06F 9/38; H03M 7/30

(52) U.S. Cl. CPC G06F 9/223; G06F 9/30156; H03M 7/6011; G06F 9/38; H03M 7/3082; G06F 9/30032

(57) ABSTRACT

Efficient encoding of high fanout communication patterns in computer programming is achieved through utilization of producer and move instructions in an instruction set architecture (ISA) that supports direct instruction communication where a producer encodes identities of consumers of results directly within an instruction. The producer instructions may fully encode the targeted consumers with an explicit target distance or utilize compressed target encoding in which a field in the instruction provides a bit vector for one-hot encoding. A variety of move instructions target different numbers of consumers and may also utilize full or compressed target encoding. In consumer paths where a producer is unable to target all consumers, a compiler may utilize various combination of producer and move instructions, using full and/or compressed target encoding to build a fanout tree that efficiently propagates the producer results to the all the targeted consumers.

### BACKGROUND

Technology trends such as growing wire delays, power consumption limits, and diminishing clock rate improvements are presenting historical instruction set architectures such as RISC (reduced instruction set computer), CISC (complex instruction set computer), and VLIW (very long instruction word) with difficult challenges. To show continued performance growth, responsibilities between programmer, compiler, and computer processor hardware will likely need to be shared in ways to maximize opportunities for discovery and exploitation of high instruction-level parallelism.

### SUMMARY

Efficient encoding of high fanout communication patterns in computer programming is achieved through utilization of producer and move instructions in an instruction set architecture (ISA) that supports direct instruction communication where a producer encodes identities of consumers of results directly within an instruction. The producer instructions may fully encode the targeted consumers with an explicit target distance or utilize compressed target encoding in which a field in the instruction provides a bit vector which specifies the list of consumer instructions. A variety of move instructions target different numbers of consumers and may also utilize full or compressed target encoding. In consumer paths where a producer is unable to target all consumers, a compiler may utilize various combinations of producer and move instructions, using full and/or compressed target encoding to build a fanout tree that efficiently propagates the producer results to all the targeted consumers.

The present high fanout communication encoding can advantageously improve the functionality of computer processors that run direct instruction communication ISAs by reducing the bit-per-instruction overhead when implementing fanouts when compared to the conventional broadcasting alternative. In addition, direct instruction communication can reduce reliance on broadcasting channels which are typically limited. The broadcast ID (identifier) field in the instructions, which enables results to be broadcast over a lightweight network to all instructions listening on that ID, can be repurposed or eliminated in some cases which may further enhance processor efficiency by increasing functionality or reducing instruction length.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. Furthermore, the claimed subject matter is not limited to implementations that solve any or all disadvantages noted in any part of this disclosure. It will be appreciated that the above-described subject matter may be implemented as a computer-controlled apparatus, a computer process, a computing system, or as an article of manufacture such as one or more computer-readable storage media. These and various other features will be apparent from a reading of the following Detailed Description and a review of the associated drawings.

### DESCRIPTION OF THE DRAWINGS

FIG. 1 shows illustrative direct instruction communication in which instructions in a block communicate directly rather than communicate using shared registers;

FIG. 2 shows an illustrative general instruction format that may be utilized for a block-based ISA (instruction set architecture) such as an Explicit Data Graph Execution (EDGE);

FIG. 3 illustratively shows a producer instruction communicating results to consumer instructions;

FIG. 4 shows an illustrative move instruction, MOV2, that may be used to implement a fanout between a producer and multiple consumers;

FIG. 5 shows an illustrative fanout tree that uses the MOV2 instruction;

FIG. 6 shows an illustrative move instruction, MOV3, that may be used to implement a fanout between a producer and multiple consumers;

FIG. 7 shows an illustrative fanout tree that uses the MOV3 instruction;

FIG. 8 shows an illustrative move instruction, MOVHF8, that may be used to implement a fanout between a producer and multiple consumers;

FIG. 9 shows an illustrative fanout tree that uses the MOVHF8 instruction;

FIG. 10 shows an illustrative move instruction, MOVHF24, that may be used to implement a fanout between a producer and multiple consumers;

FIG. 11 shows an illustrative fanout tree that uses the MOVHF24 instruction;

FIG. 12 shows an illustrative producer instruction that uses compressed target encoding;

FIG. 13 shows an illustrative fanout tree that uses a producer instruction with compressed target encoding;

FIGS. 14, 15, and 16 are flowcharts of illustrative methods;

FIG. 17 shows an illustrative computing environment in which a compiler provides encoded instructions that run on a computer processor that includes multiple cores;

FIG. 18 is a simplified block diagram of an illustrative architecture for a computer processor core; and

FIG. 19 is a simplified block diagram of an illustrative computing device.

Like reference numerals indicate like elements in the drawings. Elements are not drawn to scale unless otherwise indicated.

### DETAILED DESCRIPTION

Explicit Data Graph Execution (EDGE) is an instruction set architecture (ISA) that partitions the work between a compiler and processor hardware differently from conventional RISC (Reduced Instruction Set Computer), CISC (Complex Instruction Set Computer), or VLIW (Very Long Instruction Word) ISAs to enable high instruction-level parallelism with high energy efficiency. Instructions inside blocks execute in dataflow order, which removes the need for costly register renaming and provides power-efficient out-of-order execution.

The EDGE ISA defines the structure of, and the restrictions on, these blocks. In addition, instructions within each block employ direct Instruction Communication rather than communication through registers as in conventional ISAs. While the following discussion is provided in the context of EDGE, the disclosed techniques may also be applicable to other ISAs and microarchitectures that utilize direct instruction communication.

An EDGE compiler encodes instruction dependences explicitly using target-form encoding to thereby eliminate the need for the processor hardware to discover dependencies dynamically. Thus, for example, if instruction P produces a value for instruction C, P's instruction bits specify C as a consumer, and the processor hardware routes P's output result directly to C. The compiler explicitly encodes the data dependencies through the instruction set architecture, freeing the processor from needing to rediscover these dependencies at runtime. Computing devices using EDGE may thus be viewed as dataflow machines that enable fine grain data-driven parallel computation.

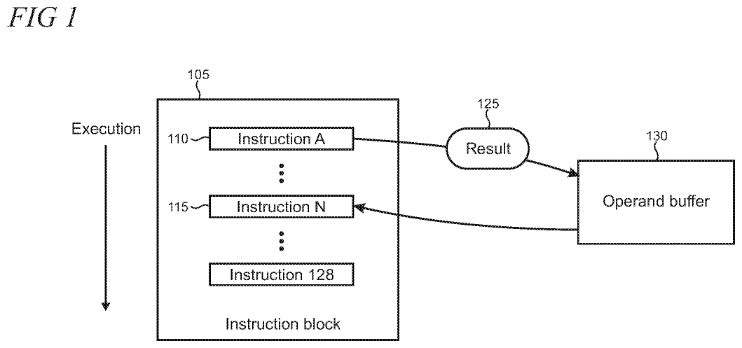

As shown in FIG. 1, target form encoding enables executing instructions 110 and 115 within a block 105 to communicate results 125 (e.g., values, operands, predicates) directly via an operand buffer 130 that is implemented in a processor core to thereby reduce the number of accesses to a physical register file. Memory and registers are only utilized for handling of less frequent inter-block communication. By utilizing such a hybrid dataflow execution model, an EDGE ISA supports imperative programming constructs and sequential memory semantics while also, for example, enabling the benefits of out-of-order execution with high efficiency.

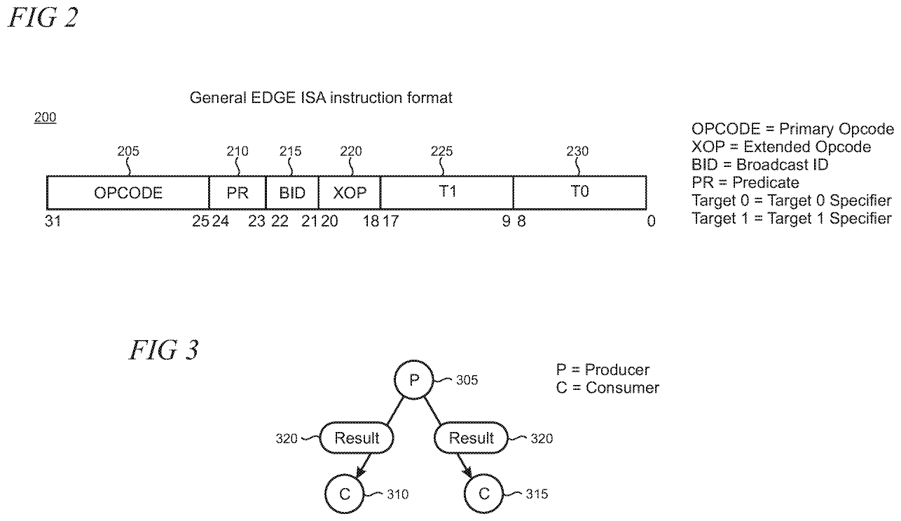

FIG. 2 shows an illustrative format for a general EDGE instruction 200. In this example, the instruction is 32 bits and supports encoding up to two target instructions using target fields 225 and 230. Each of the target fields identifies the consumer of the instruction's result which is used as an index into the operand buffer and further identifies whether the result is used as a first or second operand (e.g., operand 0, operand 1), or as a predicate.

Two fields 205 and 220 support operation code (opcode) that provides the instruction to execute along with the number of input operands to receive. The predicate field 210 indicates whether the instruction must wait on a predicate bit, and whether to execute if that bit is true or false. The broadcast ID field 215 enables results to be broadcast over a lightweight network to all instructions listening on that ID. In implementations where the present efficient encoding of high fanout communications is utilized, the broadcast ID field may be optionally repurposed for other uses.

As the instruction 200 supports dataflow encoding for two targets, as shown in FIG. 3, each instruction may be viewed as a producer 305 that can support two consumers 310 and 315 of the instruction's result 320. For instructions with more consumers than the available target fields, an EDGE compiler can build a fanout tree using multiple move (MOV) instructions.

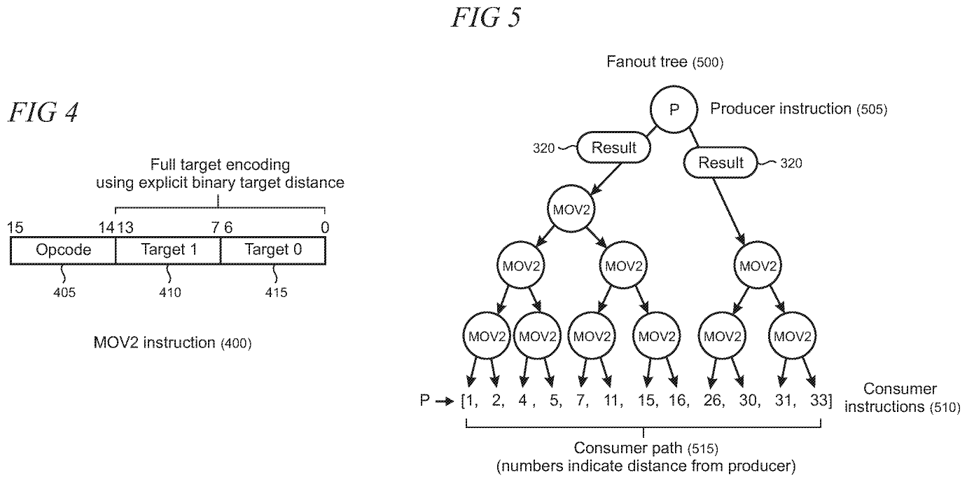

FIGS. 4 and 5 show an illustrative fanout example using the MOV2 instruction 400 in FIG. 4 that utilizes 16 bits for the move instruction opcode 405 and two targets fields 410 and 415 that encode the target consumers using an explicit binary distance (e.g., an offset or displacement) from the producer. The fanout tree 500 in FIG. 5 enables the producer 505 at the top of the tree to target a result to each of the consumers 510 at the bottom. In this particular illustrative example, the producer targets the subsequent instructions in a block as indicated by the sequence of numbers 1, 2, 4, 5, 7, 11, 15, 16, 26, 30, 31, 33 where “1” denotes the first subsequent instruction after the producer instruction, “2” the second, “4” the fourth, and so on.

The sequence thus defines a particular consumer path 515 by which results are communicated among instructions in a block. The present encoding techniques for high fanout communications may be used in scenarios in which producers and consumers are in distinct instruction blocks as well. Each MOV2 instruction propagates an input to two outputs. Thus, the ten MOV2 instructions shown in FIG. 5 enable the producer to target 12 consumer instructions. As the maximum block size is 128 instructions, each instruction target ID in the MOV2 primitive requires seven bits of instruction space to be able to name all the potential consumers. Such ability to target all of the potential consumer instructions is termed “full encoding” as used herein.

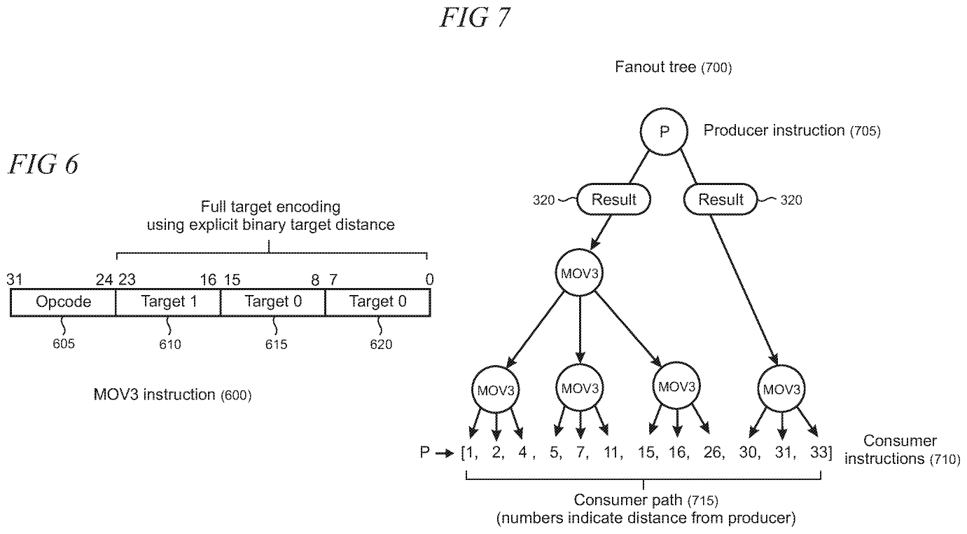

Communication fanouts can be similarly implemented using the MOV3 and MOV4 instructions. For example, FIGS. 6 and 7 show an illustrative fanout example using the MOV3 instruction 600 in FIG. 6 that utilizes 32 bits for the move instruction opcode 605 and three target fields 610, 615, and 620 that encode the target consumers using an explicit binary distance from the producer. The fanout tree 700 in FIG. 7 enables the producer 705 at the top of the tree to target a result to each of the consumers 710 at the bottom.

As shown with MOV3, the number of consumers per instruction can increase which can thereby enable a producer to reach more consumers with fewer instructions being needed overall to build the fanout tree when compared to the MOV2 instruction. However, the instruction length also increases to support the additional consumer target encodings. There can thus be tradeoffs among target reach distance, instruction count, and instruction length. Increasing the number of consumers specified by a MOV instruction, at some point, yields an unsupportable instruction length.

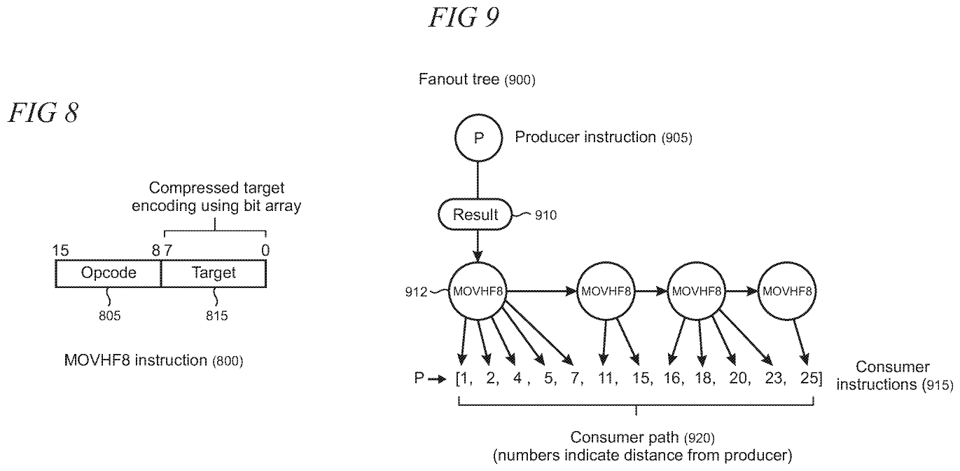

FIG. 8 shows an illustrative 16 bit high-fanout move instruction 800 called “MOVHF8” in which a single target field 815 specifies a target using a bit position indicator in a bit vector or array according to the instruction, in which multiple bits can be used to identify a given consumer instruction. Eight bits are used in the target field and eight bits are used for the instruction opcode 805. Each bit in the array in the target field is toggled to indicate which of the eight instructions subsequent to the producer instruction 905 is a target for the result 910, as shown in FIG. 9. For example, in the first MOVHF8 instruction 912, bit 0 indicates whether the instruction subsequent to the producer is targeted as a consumer for the result. Bit 1 indicates whether the second instruction subsequent to the producer consumes the result, and so forth. Utilization of the bit position indicator to specify consumer instructions is termed “compressed encoding” as used herein.

As shown, the 12 consumer instructions 915 in the consumer path 920 are targeted using four MOVHF8 instructions. Accordingly, the compressed encoding methodology using a bit vector may enable more fanout per bit of move instruction but may suffer a limitation of not being able to specify an arbitrary consumer instruction as with the full encoding methodology. The maximum target reach may also be limited as a compressed encoded target field would need a 128-bit field to reach the 128th subsequent instruction in a block. However, the MOVHF8 instruction provides an efficient encoding methodology compared to MOV2, as discussed above, and supports high fanout implementations.

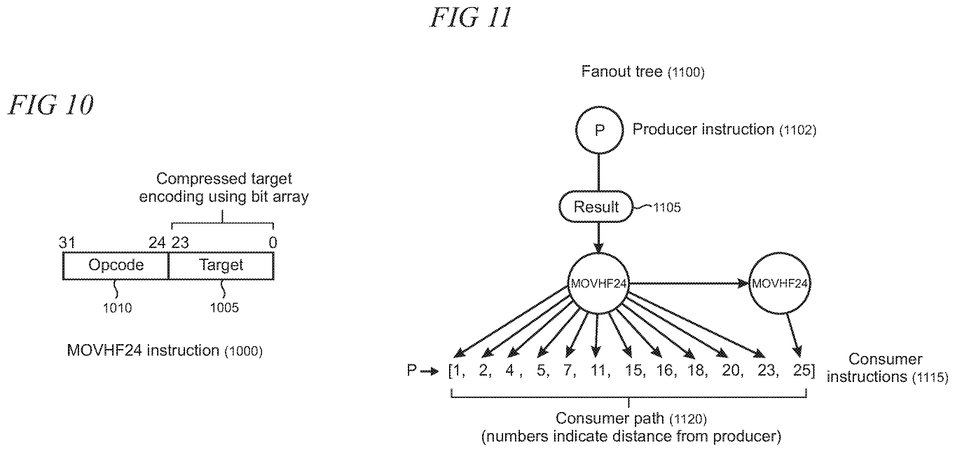

FIG. 10 shows an illustrative 32 bit high-fanout move instruction 1000 called “MOVHF24” in which a single target field 1005 specifies a target using a bit position indicator. Twenty-four bits are used in the target field and eight bits are used for the instruction opcode 1010. In a similar manner as with the MOVHF8 instruction discussed above, each bit in the target field is asserted to indicate which of the 24 instructions subsequent to the producer instruction 1102 is a target as a consumer of the result 1105, as shown in the fanout tree 1100 in FIG. 11.

As shown, two MOVHF24 instructions are utilized to communicate the result 1105 to the consumer instructions 1115 according to the path 1120. The MOVHF24 instruction provides efficient target encoding and may support large fanouts. While its reach is less limited than that of the MOVHF8 instruction, the MOVHF24 instruction is twice as big.

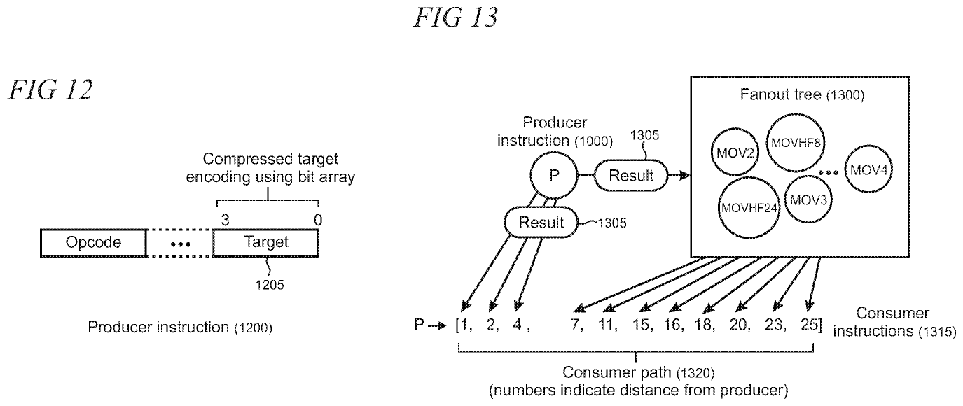

FIG. 12 shows an illustrative high fanout producer encoding scheme in which a 4-bit target field 1205 is arranged as part of a producer instruction 1200 to indicate targets for four consecutive consumers. This producer encoding follows the same compressed methodology using bit position indicators as with the MOVHF8 and MOVHF24 instructions discussed above. Each of the four bits in the producer instruction 1200 may be used to indicate which of the four subsequent instructions are consumers of the result 1205. Utilization of the high fanout producer can thus change the fanout instruction sequence from producer->MOV[ ]->consumer to producer->consumer in some instances.

The high fanout producer with compressed target encoding may be used to implement larger fanouts than those supported by the current producer instructions which are limited to two target fields as shown in FIG. 1 and discussed in the accompanying text. The direct communication between producer and consumers can reduce the utilization of move instructions in some fanout implementations.

To communicate the result to each of the consumer instructions 1315 along the path 1320 that is beyond the four subsequent consecutive instructions, a fanout tree 1300 may be utilized, as shown. Any combination of move instruction types MOV2, MOV3, MOV4, MOVVH8, MOVHF24 may be utilized in the fanout tree.

Both the fully encoded and compressed encoded producer instructions, in combination with the move instructions, can reduce overhead for given consumer paths having high fanout compared with conventional broadcast channel utilization to thereby improve processor performance. For example, in most performance benchmarks, the overhead (expressed as added bits per static instruction) is significantly less for direct dataflow communication using the techniques described herein compared to broadcast channels. However, in consumer paths that have a relatively high number of consumers relative to the overall instruction count, utilization of broadcast channels as for high fanout communications may provide improved processor performance by reducing move operations. The reduction in move operations can result in fetching and executing fewer instructions which can save energy.

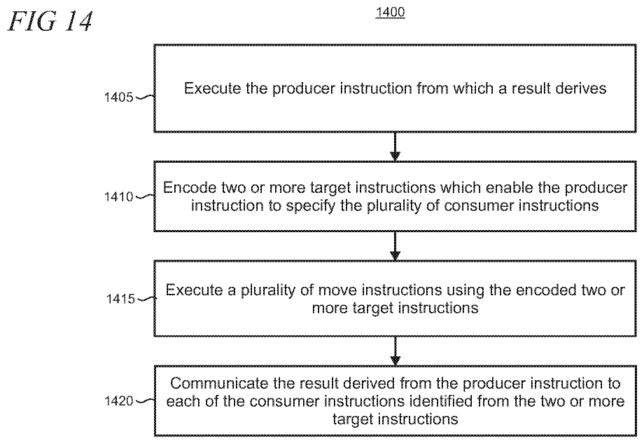

FIGS. 14, 15, and 16 show illustrative methods. Unless specifically stated, the methods or steps in the flowcharts and described below are not constrained to a particular order or sequence. In addition, some of the methods or steps thereof can occur or be performed concurrently and not all the methods or steps have to be performed in a given implementation depending on the requirements of such implementation and some methods or steps may be optionally utilized.

FIG. 14 shows a flowchart of an illustrative method 1400 that may be performed by a processor. In step 1405, a producer instruction is executed from which a result is derived. In step 1410, two or more target instructions are encoded which enable the producer instruction to specify the plurality of consumer instructions, in which at least one of the two or more target instructions identify a move instruction. In step 1415, a plurality of move instructions are executed using the encoded two or more target instructions. In step 1420, the result derived from the producer instruction is communicated to each of the consumer instructions identified from the two or more target instructions.

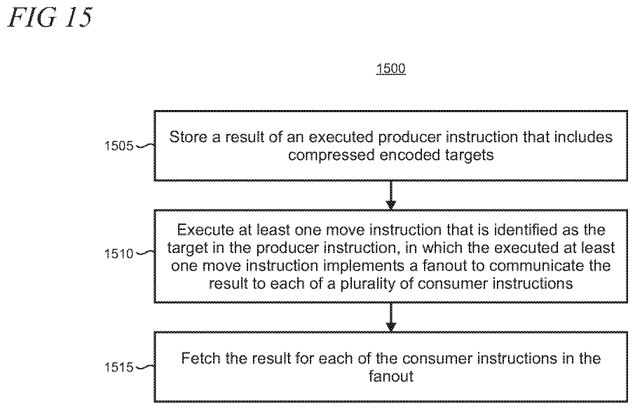

FIG. 15 shows a flowchart of an illustrative method 1500 that may be performed by a processor. In step 1505, a result of an executed producer instruction that includes compressed encoded targets is stored. In step 1510, at least one move instruction that is identified as the target in the producer instruction is executed, in which the executed at least one move instruction implements a fanout to communicate the result to each of a plurality of consumer instructions. In step 1515, the result is fetched for each of the consumer instructions in the fanout.

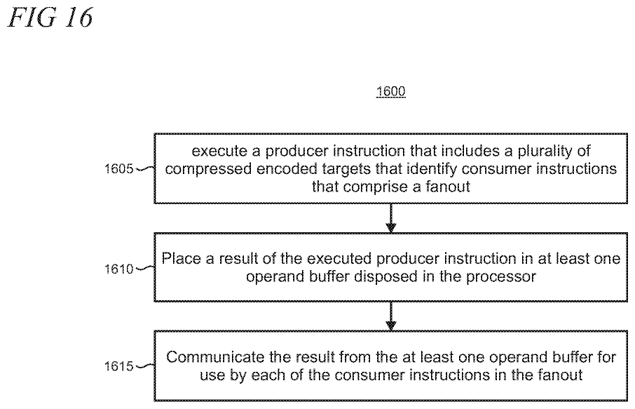

FIG. 16 shows a flowchart of an illustrative method 1600 that may be performed by a processor. In step 1605, a producer instruction that includes a plurality of compressed encoded targets that identify consumer instructions that comprise a fanout is executed. In step 1610, a result of the executed producer instruction is placed in at least one operand buffer disposed in the processor. In step 1615, the result from the at least one operand buffer is communicated for use by each of the consumer instructions in the fanout.

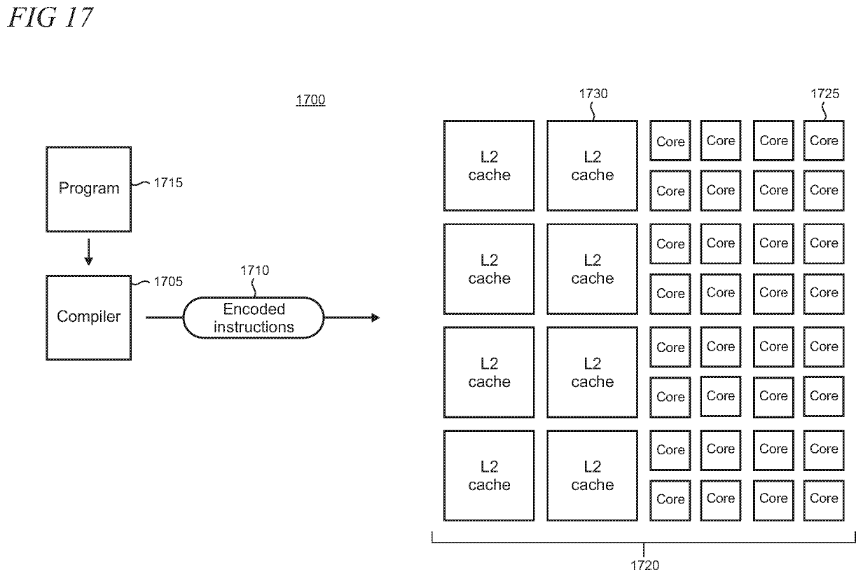

FIG. 17 shows an illustrative computing environment 1700 that may facilitate practice of present efficient encoding of high fanout communications. The environment includes a compiler 1705 that may be utilized to generate encoded machine-executable instructions 1710 from a program 1715. The instructions 1710 can be handled by a processor architecture 1720 that is configured to process blocks of instructions of variable size containing, for example, between 4 and 128 instructions. The processor architecture can support an EDGE ISA in some implementations.

The processor architecture 20 typically includes multiple processor cores (representatively indicated by reference numeral 1725), in a tiled configuration, that are interconnected by an on-chip network (not shown) and further interoperated with one or more level 2 (L2) caches (representatively indicated by reference numeral 1730). While the number and configuration of cores and caches can vary by implementation, it is noted that the physical cores can be merged together, in a process termed “composing,” during runtime of the program 1715, into one or more larger logical processors that can enable more processing power to be devoted to a program execution. Alternatively, when program execution supports suitable thread-level parallelism, the cores 1725 can be split, in a process called “decomposing,” to work independently and execute instructions from independent threads.

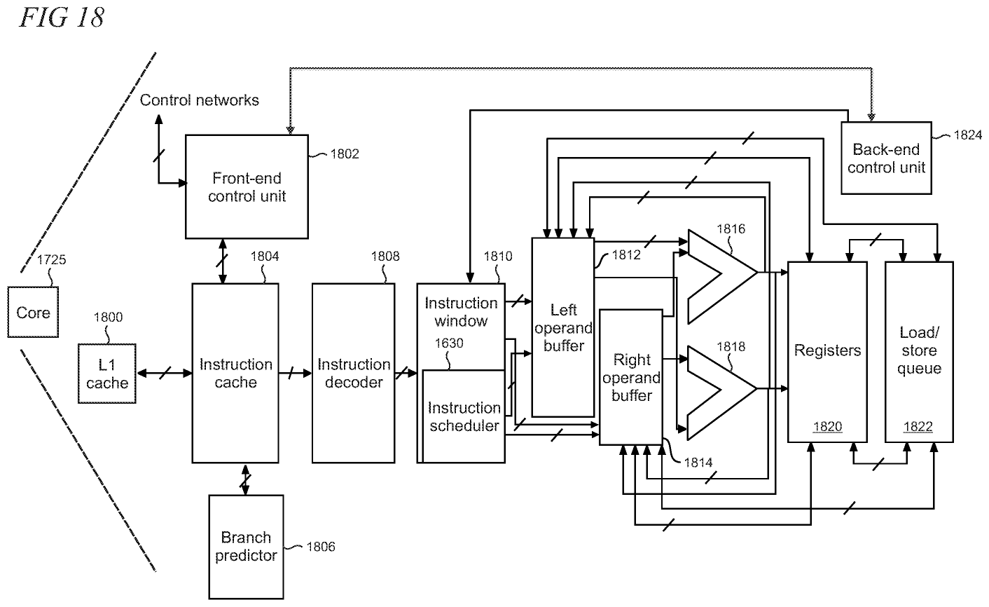

FIG. 18 is a simplified block diagram of a microarchitecture of an illustrative processor core 1725. As shown, the processor core 1725 may include an L1 cache 1800, a front-end control unit 1802, an instruction cache 1804, a branch predictor 1806, an instruction decoder 1808, an instruction window 1810, a left operand buffer 1812, a right operand buffer 1814, an arithmetic logic unit (ALU) 1816, a second ALU 1818, registers 1820, and a load/store queue 1822. In some cases, the buses (indicated by the arrows) may carry data and instructions while in other cases, the buses may carry data (e.g., operands) or control signals. For example, the front-end control unit 1802 may communicate, via a bus that carries only control signals, with other control networks. Although FIG. 18 shows a certain number of illustrative components for the processor core 1725, that are arranged in a particular arrangement, there may be more or fewer components arranged differently depending on the needs of a particular implementation.

The front-end control unit 1802 may include circuitry configured to control the flow of information through the processor core and circuitry to coordinate activities within it. The front-end control unit 1802 also may include circuitry to implement a finite state machine (FSM) in which states enumerate each of the operating configurations that the processor core may take. Using opcodes (as described below) and/or other inputs (e.g., hardware-level signals), the FSM circuits in the front-end control unit 1802 can determine the next state and control outputs.

Accordingly, the front-end control unit 1802 can fetch instructions from the instruction cache 1804 for processing by the instruction decoder 1808. The front-end control unit 1802 may exchange control information with other portions of the processor core 1725 over control networks or buses. For example, the front-end control unit may exchange control information with a back-end control unit. The front-end and back-end control units may be integrated into a single control unit in some implementations.

The front-end control unit 1802 may also coordinate and manage control of various cores and other parts of the processor architecture 1720 (FIG. 17). Accordingly, for example, blocks of instructions may be simultaneously executing on multiple cores and the front-end control unit 1802 may exchange control information via control networks with other cores to ensure synchronization, as needed, for execution of the various blocks of instructions.

The front-end control unit 1802 may further process control information and meta-information regarding blocks of instructions that are executed atomically. For example, the front-end control unit 1802 can process block headers that are associated with blocks of instructions. The block header may include control information and/or meta-information regarding the block of instructions. Accordingly, the front-end control unit 1802 can include combinational logic, state machines, and temporary storage units, such as flip-flops to process the various fields in the block header.

The front-end control unit 1802 may fetch and decode a single instruction or multiple instructions per clock cycle. The decoded instructions may be stored in an instruction window 1810 that is implemented in processor core hardware as a buffer. The instruction window 1810 can support an instruction scheduler 1830, in some implementations, which may keep a ready state of each decoded instruction's inputs such as predications and operands. For example, when all of its inputs (if any) are ready, a given instruction may be woken up by instruction scheduler 1830 and be ready to issue.

Before an instruction is issued, any operands required by the instruction may be stored in the left operand buffer 1812 and/or the right operand buffer 1814, as needed. Depending on the opcode of the instruction, operations may be performed on the operands using ALU 1816 and/or ALU 1818 or other functional units. The outputs of an ALU may be stored in an operand buffer or stored in one or more registers 1820. Store operations that issue in a data flow order may be queued in load/store queue 1822 until a block of instructions commits. When the block of instructions commits, the load/store queue 1822 may write the committed block's stores to a memory. The branch predictor 1806 may process block header information relating to branch exit types and factor that information in making branch predictions.

As noted above, the processor architecture 1720 (FIG. 17) typically utilizes instructions organized in blocks that are fetched, executed, and committed atomically. Thus, a processor core may fetch the instructions belonging to a single block en masse, map them to the execution resources inside the processor core, execute the instructions, and commit their results in an atomic fashion. The processor may either commit the results of all instructions or nullify the execution of the entire block. Instructions inside a block may execute in a data flow order. In addition, the processor may permit the instructions inside a block to communicate directly with each other using messages or other suitable forms of communication. Thus, an instruction that produces a result may, instead of writing the result to a register file, communicate that result to another instruction in the block that consumes the result. As an example, an instruction that adds the values stored in registers R1 and R2 may be expressed as shown in Table 1 below:

TABLE 1

I[0] READ R1 T[2R];
I[1]READ R2 T[2L];
I[2] ADD T[3L].

In this way, source operands are not specified with the instruction, and instead, they are specified by the instructions that target the ADD instruction. The compiler 1705 (FIG. 17) may explicitly encode the control and data dependencies during compilation of the instructions 1710 to thereby free the processor core from rediscovering these dependencies at runtime. This may advantageously result in reduced processor load and energy savings during execution of these instructions. As an example, the compiler may use predication to convert all control dependencies into data flow instructions. Using these techniques, the number of accesses to power-hungry register files may be reduced.

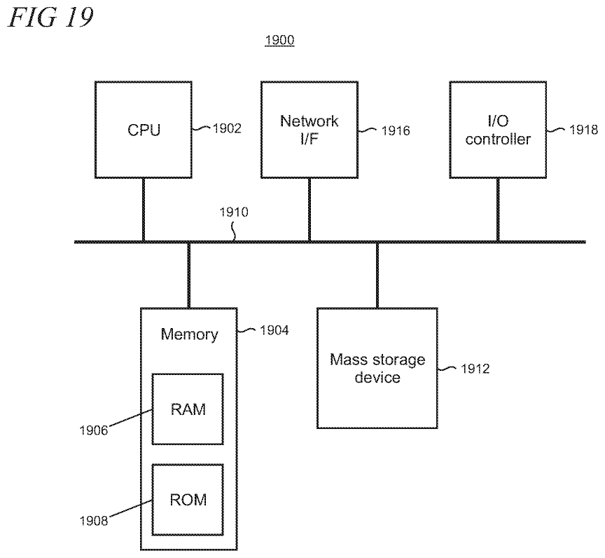

FIG. 19 shows an illustrative architecture 1900 for a computing device that is capable of executing the various components described herein for the present efficient encoding of high fan out communications. The architecture 1900 illustrated in FIG. 19 includes one or more processors 1902 (e.g., central processing unit, dedicated AI (artificial intelligence) chip, graphics processing unit, etc.), a system memory 1904, including RAM (random access memory) 1906 and ROM (read only memory) 1908, and a system bus 1910 that operatively and functionally couples the components in the architecture 1900. A basic input/output system containing the basic routines that help to transfer information between elements within the architecture 1900, such as during startup, is typically stored in the ROM 1908. The architecture 1900 further includes a mass storage device 1912 for storing software code or other computer-executed code that is utilized to implement applications, the file system, and the operating system. The mass storage device 1912 is connected to the processor 1902 through a mass storage controller (not shown) connected to the bus 1910. The mass storage device 1912 and its associated computer-readable storage media provide non-volatile storage for the architecture 1900. Although the description of computer-readable storage media contained herein refers to a mass storage device, such as a hard disk or CD-ROM drive, it may be appreciated by those skilled in the art that computer-readable storage media can be any available storage media that can be accessed by the architecture 1900.

By way of example, and not limitation, computer-readable storage media may include volatile and non-volatile, removable and non-removable media implemented in any method or technology for storage of information such as computer-readable instructions, data structures, program modules, or other data. For example, computer-readable media includes, but is not limited to, RAM, ROM, EPROM (erasable programmable read only memory), EEPROM (electrically erasable programmable read only memory), Flash memory or other solid state memory technology, CD-ROM, DVDs, HD-DVD (High Definition DVD), Blu-ray or other optical storage, magnetic cassettes, magnetic tape, magnetic disk storage or other magnetic storage devices, or any other medium which can be used to store the desired information and which can be accessed by the architecture 1900.

According to various embodiments, the architecture 1900 may operate in a networked environment using logical connections to remote computers through a network. The architecture 1900 may connect to the network through a network interface unit 1916 connected to the bus 1910. It may be appreciated that the network interface unit 1916 also may be utilized to connect to other types of networks and remote computer systems. The architecture 1900 also may include an input/output controller 1918 for receiving and processing input from a number of other devices, including a keyboard, mouse, touchpad, touchscreen, control devices such as buttons and switches, or electronic stylus (not shown in FIG. 19). Similarly, the input/output controller 1918 may provide output to a display screen, user interface, a printer, or other type of output device (also not shown in FIG. 19).

It may be appreciated that the software components described herein may, when loaded into the processor 1902 and executed, transform the processor 1902 and the overall architecture 1900 from a general-purpose computing system into a special-purpose computing system customized to facilitate the functionality presented herein. The processor 1902 may be constructed from any number of transistors or other discrete circuit elements, which may individually or collectively assume any number of states. More specifically, the processor 1902 may operate as a finite-state machine, in response to executable instructions contained within the software modules disclosed herein. These computer-executable instructions may transform the processor 1902 by specifying how the processor 1902 transitions between states, thereby transforming the transistors or other discrete hardware elements constituting the processor 1902.

Encoding the software modules presented herein also may transform the physical structure of the computer-readable storage media presented herein. The specific transformation of physical structure may depend on various factors, in different implementations of this description. Examples of such factors may include, but are not limited to, the technology used to implement the computer-readable storage media, whether the computer-readable storage media is characterized as primary or secondary storage, and the like. For example, if the computer-readable storage media is implemented as semiconductor-based memory, the software disclosed herein may be encoded on the computer-readable storage media by transforming the physical state of the semiconductor memory. For example, the software may transform the state of transistors, capacitors, or other discrete circuit elements constituting the semiconductor memory. The software also may transform the physical state of such components in order to store data thereupon.

As another example, the computer-readable storage media disclosed herein may be implemented using magnetic or optical technology. In such implementations, the software presented herein may transform the physical state of magnetic or optical media, when the software is encoded therein. These transformations may include altering the magnetic characteristics of particular locations within given magnetic media. These transformations also may include altering the physical features or characteristics of particular locations within given optical media to change the optical characteristics of those locations. Other transformations of physical media are possible without departing from the scope and spirit of the present description, with the foregoing examples provided only to facilitate this discussion.

Various exemplary embodiments of the present efficient encoding of high fanout communications are now presented by way of illustration and not as an exhaustive list of all embodiments. An example includes a method for communicating a result from a producer instruction to a plurality of consumer instructions using a fanout, the method comprising: executing the producer instruction from which a result derives; encoding two or more target instructions which enable the producer instruction to specify the plurality of consumer instructions, in which at least one of the two or more target instructions identify a move instruction; executing a plurality of move instructions using the encoded two or more target instructions; and communicating the result derived from the producer instruction to each of the consumer instructions identified from the two or more target instructions.

In another example, the method includes at least one move instruction in the plurality identifying two target instructions using full target encoding comprising specification of an explicit binary target distance between the move instruction and the target instruction. In another example, the method includes at least one move instruction identifying three or four target instructions using full target encoding comprising specification of an explicit binary target distance between the move instruction and the target instruction. In another example, the method includes at least one move instruction identifying four or more target instructions using compressed target encoding. In another example, the method includes multiple different instruction lengths being utilized to accommodate differing scenarios to realize a fanout. In another example, the method includes multiple different instruction lengths being utilized to realize a given fanout situation by a number of instructions and a size of instructions necessary to realize the fanout. In another example, the method includes the producer instruction supporting full target encoding or compressed target encoding of two or more target instructions. In another example, the method includes the producer and consumer instructions sharing a common instruction block or being in distinct instruction blocks. In another example, the method includes the target instructions being encoded using a bit vector.

A further example includes an instruction block-based microarchitecture, comprising: a control unit; and an instruction window configured to store decoded instruction blocks associated with a program to be under control of the control unit in which the control includes operations to: store a result of an executed producer instruction that includes compressed encoded targets, execute at least one move instruction that is identified as a target in the producer instruction, in which the executed at least one move instruction implements a fanout to communicate the result to each of a plurality of consumer instructions, and fetch the result for each of the consumer instructions in the fanout.

In another example, the producer instruction encodes at least two target instructions. In another example, at least one move instruction identifies at least two subsequent target instructions in the fanout. In another example, the at least one move instruction identifies one of two, three, four, eight, or 24 subsequent target instructions in the fanout. In another example, the at least one move instruction uses one of full target encoding or compressed target encoding. In another example, the at least one move instruction uses compressed target encoding using a bit position indicator where each bit in the indicator corresponds to a respective subsequent target instruction.

A further example includes one or more hardware-based non-transitory computer readable memory devices storing computer-executable instructions which, upon execution by a processor in a computing device, cause the computing device to execute a producer instruction that includes a plurality of compressed encoded targets that identify consumer instructions that comprise a fanout; place a result of the executed producer instruction in at least one operand buffer disposed in the processor; and communicate the result from the at least one operand buffer for use by each of the consumer instructions in the fanout.

In another example, the producer instruction includes a target field and the compressed encoded targets are encoded using a bit vector in the target field. In another example, the bit vector encoding specifies multiple consumer instructions based on a bit position. In another example, the bit vector is at least 4-bits in length. In another example, the processor uses an EDGE (Explicit Data Graph Execution) block-based instruction set architecture (ISA).

In light of the above, it may be appreciated that many types of physical transformations take place in the architecture 1900 in order to store and execute the software components presented herein. It also may be appreciated that the architecture 1900 may include other types of computing devices, including wearable devices, handheld computers, embedded computer systems, smartphones, PDAs, and other types of computing devices known to those skilled in the art. It is also contemplated that the architecture 1900 may not include all of the components shown in FIG. 19, may include other components that are not explicitly shown in FIG. 19, or may utilize an architecture completely different from that shown in FIG. 19.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed:

1. A method for communicating a result from a producer instruction to a plurality of consumer instructions using a fanout, the method comprising:
executing the producer instruction from which a result derives;
encoding two or more target instructions which enable the producer instruction to specify the plurality of consumer instructions, in which at least one of the two or more target instructions identify a move instruction;
executing a plurality of move instructions using the encoded two or more target instructions; and
communicating the result derived from the producer instruction to each of the consumer instructions identified from the two or more target instructions.

2. The method of claim 1 in which at least one move instruction in the plurality identifies two target instructions using full target encoding comprising specification of an explicit binary target distance between the move instruction and the target instruction.

3. The method of claim 1 in which at least one move instruction identifies three or four target instructions using full target encoding comprising specification of an explicit binary target distance between the move instruction and the target instruction

4. The method of claim 1 in which at least one move instruction identifies four or more target instructions using compressed target encoding.

5. The method of claim 1 in which multiple different instruction lengths are utilized to accommodate differing scenarios to realize a fanout.

6. The method of claim 5 in which the multiple different instruction lengths are utilized to realize a given fanout situation by a number of instructions and a size of instructions necessary to realize the fanout.

7. The method of claim 1 in which the producer instruction supports full target encoding or compressed target encoding of two or more target instructions.

8. The method of claim 1 in which the producer and consumer instructions share a common instruction block or are in distinct instruction blocks.

9. The method of claim 1 in which the target instructions are encoded using a bit vector.

10. An instruction block-based microarchitecture, comprising:
a control unit; and
an instruction window configured to store decoded instruction blocks associated with a program to be under control of the control unit in which the control includes operations to:
store a result of an executed producer instruction that includes compressed encoded targets,
execute at least one move instruction that is identified as a target in the producer instruction, in which the executed at least one move instruction implements a fanout to communicate the result to each of a plurality of consumer instructions, and
fetch the result for each of the consumer instructions in the fanout.

11. The instruction block-based microarchitecture of claim 10 in which the producer instruction encodes at least two target instructions.

12. The instruction block-based microarchitecture of claim 10 in which the at least one move instruction identifies at least two subsequent target instructions in the fanout.

13. The instruction block-based microarchitecture of claim 10 in which the at least one move instruction identifies one of two, three, four, eight, or 24 subsequent target instructions in the fanout.

14. The instruction block-based microarchitecture of claim 10 in which the at least one move instruction uses one of full target encoding or compressed target encoding.

15. The instruction block-based microarchitecture of claim 14 in which the at least one move instruction uses compressed target encoding using a bit position indicator where each bit in the indicator corresponds to a respective subsequent target instruction.

16. One or more hardware-based non-transitory computer readable memory devices storing computer-executable instructions which, upon execution by a processor in a computing device, cause the computing device to
execute a producer instruction that includes a plurality of compressed encoded targets that identify consumer instructions that comprise a fanout;
place a result of the executed producer instruction in at least one operand buffer disposed in the processor; and
communicate the result from the at least one operand buffer for use by each of the consumer instructions in the fanout.

17. The one or more hardware-based non-transitory computer readable memory devices of claim 16 in which the producer instruction includes a target field and the compressed encoded targets are encoded using a bit vector in the target field.

18. The one or more hardware-based non-transitory computer readable memory devices of claim 17 in which the bit vector encoding specifies multiple consumer instructions based on a bit position.

19. The one or more hardware-based non-transitory computer readable memory devices of claim 17 in which the bit vector is at least 4-bits in length.

20. The one or more hardware-based non-transitory computer readable memory devices of claim 16 in which the processor uses an EDGE (Explicit Data Graph Execution) block-based instruction set architecture (ISA).
